(19) United States
(12) Patent Application Publication
(10) Pub. No.: US 2024/0271269 A1
(43) Pub. Date: Aug. 15, 2024

(54) EVAPORATION COATING APPARATUS

(71) Applicants: Wuhan China Star Optoelectronics Technology Co.,Ltd., Wuhan, Hubei (CN); Wuhan China Star Optoelectronics Semiconductor Display Technology Co., Ltd., Wuhan, Hubei (CN)

(72) Inventors: Ruiting HE, Wuhan, Hubei (CN); Xiaokang LI, Wuhan, Hubei (CN)

(73) Assignees: Wuhan China Star Optoelectronics Technology Co., Ltd., Wuhan, Hubei (CN); Wuhan China Star Optoelectronics Semiconductor Display Technology Co., Ltd., Wuhan, Hubei (CN)

(21) Appl. No.: 17/293,052

(22) PCT Filed: Apr. 21, 2021
(86) PCT No.: PCT/CN2021/088622

§ 371 Date: May 12, 2021

(30) Foreign Application Priority Data
Apr. 12, 2021 (CN) 202110390438.5

(51) Int. Cl. C23C 14/24; C23C 14/04; C23C 14/50

(52) U.S. Cl. CPC C23C 14/243; C23C 14/042; C23C 14/50

(57) ABSTRACT

An evaporation device is disclosed, which includes a crucible body, which is a hollow plate including a cavity; a plurality of discharge pipes evenly distributed on a bottom surface of the crucible body, wherein an outlet at one end of each of the plurality of discharge pipes is communicated with the cavity, and the outlet at another end of each of the plurality of discharge pipes faces a ground; a plurality of crucible barrels, each of the crucible barrels is disposed between two or more of adjacent ones of the discharge pipes and includes a barrel opening connected to the cavity of the hollow plate; and a plurality of inlets arranged on a top surface of the crucible body and communicated with the cavity, wherein each of the plurality of inlets is arranged opposite to the barrel opening of each of the plurality of crucible barrels.

### BACKGROUND OF INVENTION

### Field of Invention

The present application relates to a heating device, in particular to an evaporation coating apparatus used as an evaporation source to heat and vaporize and thus, deposit a coating material on a surface of a substrate or a workpiece.

### Description of Prior Art

Currently, screens widely used in the market include liquid crystal displays (LCDs) and organic light-emitting diode (OLED) displays, and OLED displays are mainly used in small-sized panels. Compared with the LCD screens, OLED display screens have advantages of lightness and thinness, low power consumption, high contrast, high color gamut, and can realize flexible display, thus are the development trend of the next generation of displays.

OLED display includes passive matrix light-emitting diode (PMOLED) displays and active matrix light-emitting diode (AMOLED) displays. The AMOLED displays can be realized by a method of combining a low temperature poly-silicon (LTPS) backplane and fine metal mask (FMM), and a method of combining an oxide backplane, white organic light-emitting diode (WOLED), and color filter. The former is mainly used in small-sized panels, corresponding to mobile phones and mobile applications; and the latter is mainly used in large-sized panels, corresponding to applications such as monitors and TVs. Now the method of combining LTPS backplane and fine metal mask has initially matured, and its mass production has been achieved. Countries and regions for OLED display technology and industries are mainly concentrated in Asia, and the OLED market has a bright future.

The fine metal mask (FMM Mask) mode is to evaporate the OLED material on the LTPS backplane according to a predetermined procedure through the evaporation method, and red, green, and blue devices are formed by using patterns on the fine metal mask. Evaporation coating is carried out in a vacuum chamber, linear evaporation sources are used in mass production, and linear crucibles are used as crucibles, which are heated by an external heating wire. The evaporation source is located under an evaporation substrate, and the fine metal mask is placed between the evaporation substrate and the evaporation source. An evaporation surface of the evaporation substrate faces down, and fixed points are around the evaporation substrate. The evaporation substrate has a great amount of sagging, and when it is aligned with the fine metal mask plate that is welded flatly, and it will cause easy misalignment and inadequate bonding, and result in poor color mixing of OLEDs, which seriously affects the yield rate. In addition, a hardware (a finger) that fixes the evaporation substrate will become loose and misaligned as a production volume increases due to loading of substrate weight, and requires regular position correction, resulting in a lot of manpower and waste of production capacity.

### SUMMARY OF INVENTION

An object of the present disclosure is to provide an evaporation coating apparatus to solve the technical problems of easy misalignment and inadequate bonding between an evaporation substrate and a fine metal mask, as well as the easy loosening and misalignment of the hardware for fixing the evaporation substrate.

In order to achieve the above object, the present disclosure provides an evaporation coating apparatus, including: a crucible body, wherein the crucible body is a hollow plate including a cavity; a plurality of discharge pipes evenly distributed on a bottom surface of the crucible body, wherein an outlet at one end of each of the plurality of discharge pipes is communicated with the cavity, and the outlet at another end of each of the plurality of discharge pipes faces a ground; a plurality of crucible barrels, wherein each of the plurality of crucible barrels is disposed between two or more of adjacent ones of the discharge pipes, and each of the plurality of crucible barrels includes a barrel opening connected to the cavity of the hollow plate; and a plurality of inlets arranged on a top surface of the crucible body and communicated with the cavity, wherein each of the plurality of inlets is arranged opposite to the barrel opening of each of the plurality of crucible barrels.

Further, the crucible body is a flat plate; and a ratio of a volume of the cavity to a volume of the crucible body is 0.7-0.95.

Further, the discharge pipes are linear, and a central axis of each of the plurality of discharge pipes is perpendicular to a plane where a bottom surface of the hollow plate is located.

Further, a distance between adjacent ones of the discharge pipes is 10-40 mm.

Further, the evaporation coating apparatus further includes a nozzle connected to the outlet at the another end of each of the plurality of discharge pipes that faces the ground.

Further, a ratio of an aperture of the nozzle to an inner diameter of the outlet of each of the plurality of discharge pipes is less than 0.5; or the ratio of the aperture of the nozzle to the inner diameter of the outlet of each of the plurality of discharge pipes is 1.

Further, each of the plurality of the crucible barrels is a column having a height less than or equal to a length of each of the plurality of discharge pipes.

Further, the evaporation coating apparatus further includes an evaporation source, wherein the evaporation source is an electric heating wire surrounding the plurality of crucible barrels and/or the plurality of discharge pipes.

Further, the plurality of discharge pipes and the plurality of crucible barrels are arranged in a crucible matrix; and the evaporation source is an electric heating wire surrounding the crucible matrix.

Further, the evaporation coating apparatus further includes a stage configured to place a substrate; a fixing device installed at an edge of the stage to fix the substrate; and a mask plate disposed above the substrate.

Technical effect of the present disclosure is to provide an evaporation coating apparatus, wherein a substrate is placed on a flat stage, discharge pipes are arranged on the crucible body, a nozzle faces the ground, an evaporation source is located above the substrate, a mask plate is placed between the substrate and the evaporation source, and an evaporation surface of the substrate faces upward. The substrate is coated by evaporation under the condition of zero sagging, and the mask will not be squeezed by the substrate, so as to improve the stability and service life of the mask. A fixing device may be simple hardware, which does not need to bear a weight of the substrate itself, and thus is not easy to loosen and displace, and does not require frequent correction. Therefore, the evaporation coating apparatus can effectively improve yield, increase production capacity, save manpower, improve the stability and service life of the fine mask, thus providing a qualitative improvement to the OLED industry.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic structural diagram of an evaporation coating apparatus provided in Embodiment 1 of the present application.

FIG. 2 is a schematic structural diagram of a crucible body provided in Embodiment 1 of the present application.

FIG. 3 is a schematic structural diagram of an evaporation coating apparatus provided in Embodiment 2 of the present application.

Elements in the drawings are designated by reference numerals listed below.
100a, 100b evaporation coating apparatus;
1. crucible body; 2. discharge pipe;
3. crucible pipe; 4. inlet;
5. nozzle; 6. sealing cover;
7. evaporation source; 8. stage;
9. fixing device; 10. mask plate;
11. substrate; 101. cavity;
201. outlet; 301. barrel opening

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them.

In addition, it should be understood that the specific implementations described here are only used to illustrate and explain the application, and are not used to limit the application. In the description of this application, it should be understood that the terms “center”, “longitudinal”, “transverse”, “length”, “width”, “thickness”, “upper”, “lower”, “front”, “post”, “left”, “right”, “vertical”, “horizontal”, “top”, “bottom”, and the like are based on the orientation or positional relationship shown in the drawings, and is merely for the convenience of describing the present invention and simplifying the description, rather than indicating or implying that the device or element referred to must have a specific orientation, structure and operation in a specific orientation, which should not be construed as limitations on the present invention.

### Embodiment 1

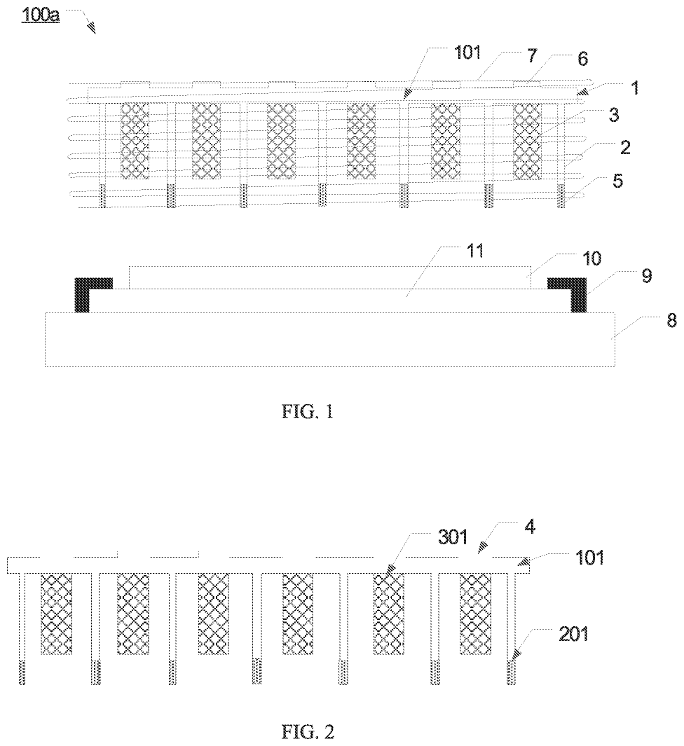

FIG. 1 is a schematic structural diagram of an evaporation coating apparatus provided by an embodiment of the present application; and FIG. 2 is a schematic structural diagram of a crucible body provided by an embodiment of the present application.

As shown in FIG. 1, this embodiment provides an evaporation coating apparatus 100a, which includes a crucible body 1, a plurality of discharge pipes 2, a plurality of crucible barrels 3, a plurality of inlets 4, a nozzle 5, a sealing cover 6, an evaporation source 7, a stage 8, a fixing device 9, and a mask plate 10.

The crucible body 1 is a hollow plate and includes a cavity 101. The crucible body 1 is a flat plate, and a ratio of a volume of the cavity 101 to a volume of the crucible body 1 is 0.7-0.95. On the one hand, a height of the crucible body 1 is reduced, thus reducing a space occupied by the evaporation coating apparatus 100a. On the other hand, during the evaporation coating process, a movement space of the evaporation coating material in the cavity 101 is reduced to prevent heat dissipation and ensure that the evaporation coating material effectively forms into a film on a substrate 11.

A plurality of discharge pipes 2 are evenly distributed on a bottom surface of the crucible body 1, which is beneficial to uniformity of subsequent film formation. An outlet 201 at one end of the discharging pipe 2 is connected to the cavity 101, and the outlet 201 at the other end of the discharging pipe 2 faces a ground, so that the substrate 11 is arranged below the discharging port. The discharge pipe 2 is linear, and a central axis of the discharge pipe 2 is perpendicular to a plane of a bottom surface of the hollow plate, so as to ensure that a direction of each of the outlets is consistent. A distance between adjacent ones of the discharging pipes 2 is 10-40 mm, so as to further ensure that a film can be formed at any position on the substrate 11.

Each of the crucible barrels 3 is arranged between two or more of adjacent ones of the discharge pipes 2; and each of the plurality of crucible barrels 3 includes a barrel opening 301 connected to the cavity 101 of the hollow plate. The crucible barrel 3 is a column and has a height less than or equal to a length of the discharge pipe 2, so as to ensure that the material ejected from the discharge pipes 2 is not blocked by the crucible barrels 3, thus improving the uniformity of film formation.

A plurality of inlets 4 are provided on a top surface of the crucible body 1 and is connected to the cavity 101. Each of the inlets 4 is arranged opposite to the barrel opening 301 of a crucible barrel 3, which is convenient for adding materials, so that the material can directly enter the crucible barrels 3 from the inlets 4 and does not overflow from the crucible barrels 3 to the discharge pipes 2.

The nozzle 5 is connected to the outlet 201 at an end of the discharge pipe 2 facing the ground. In this embodiment, a ratio of an aperture of the nozzle 5 to an inner diameter of the outlet 201 of each of the plurality of discharge pipes 2 is 1, that is, the nozzle 5 and the discharge pipe 2 may be an integral structure. The integral structure is detachably mounted to the crucible body 1 to facilitate cleaning and replacement of the nozzle 5 and the discharge pipes 2. In other embodiments, the nozzle 5 is detachably mounted to the outlet 201 of the discharge pipe, so that the nozzle 5 can also be cleaned and replaced.

The sealing cover 6 is detachably mounted to the inlet 4, and a size of the sealing cover 6 is consistent with a size of the inlet 4. When adding the material, the sealing cover 6 can be unscrewed to facilitate the addition of the material. During evaporation coating, the sealing cover 6 can be screwed to ensure the tightness of the crucible body 1 and prevent the evaporation material from overflowing from the inlets 4.

The evaporation source 7 is used to heat the crucible barrels 3. A plurality of discharge pipes 2 and a plurality of crucible barrels 3 are arranged in a crucible matrix; and the evaporation source 7 is an electric heating wire, which surrounds the crucible matrix. In other embodiments, the evaporation source 7 is an electric heating wire that surrounds the crucible barrels 3 or the discharge pipes 2; or the electric heating wire surrounds the crucible barrels 3 as well as the discharge pipes 2.

The stage 8 is used to place a substrate 11. The fixing device 9 is installed at an edge of the stage 8 to fix the substrate 11. The mask 10 is disposed above the substrate 11, and the mask 10 is a fine metal mask (FMM) 10.

This embodiment provides an evaporation coating apparatus 100a, the substrate 11 is placed on a flat stage 8, the discharge pipes 2 are arranged on the crucible body 1, the nozzle 5 faces the ground, and the evaporation source 7 is located above the substrate 11, a mask 10 is placed between the substrate 11 and the evaporation source 7, and an evaporation surface of the substrate 11 faces upward.

Compared with the prior art, the present disclosure changes the traditional upward evaporation coating method to the downward evaporation coating method, so that the substrate 11 can be evaporation coated under the condition of zero sagging of the substrate 11 during the evaporation coating process, which effectively improves the problem of poor color mixing caused by a great amount of sagging of the substrate 11. The downward evaporation coating apparatus 100a can prevent the substrate 11 from squeezing the mask plate 10, so as to improve the stability and service life of the mask plate 10. During the alignment process, the substrate 11 and the mask plate realize plane-to-plane alignment, and fit more closely since misalignment is not easy to occur in the local alignment. The fixing device 9 of this embodiment may be simple hardware, which does not need to bear the weight of the substrate 11 itself, and thus is not easy to loosen or misalign, and does not require frequent correction.

Therefore, the present embodiment provides an evaporation coating apparatus 100a, which can effectively improve yield, increase production capacity, save manpower, and improve the stability and service life of the fine mask 10, thereby qualitatively improving the OLED industry.

### Embodiment 2

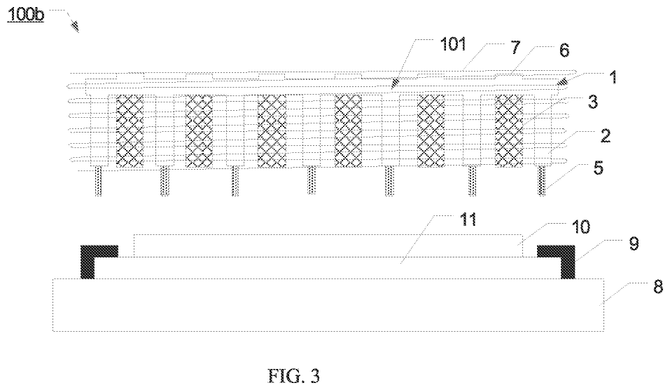

FIG. 3 is a schematic structural diagram of an evaporation coating apparatus provided by an embodiment of the present application.

As shown in FIG. 3, this embodiment provides an evaporation coating apparatus 100b, which includes most of the technical features of Embodiment 1, the difference is that a ratio of the aperture of the nozzle 5 to the inner diameter of the outlet 201 of the discharge pipe is less than 0.5.

It should be noted that, referring to FIG. 1, when the ratio of the aperture of the nozzle 5 to the inner diameter of the outlet 201 of the discharge pipe of Embodiment 1 is 1, the gas flow rate of the crucible body 1 is relatively large, so the pressure on the discharge pipe 2 is relatively high, and the nozzle 5 cannot eject the material in time, which easily causes clogging of the nozzle.

Compared with Embodiment 1, still referring to FIG. 3, in this embodiment, a ratio of the aperture of the nozzle 5 to the inner diameter of the outlet 201 of the discharge pipe is less than 0.5, which can alleviate the pressure of the discharge pipe 2, thereby reducing the risk of clogging of the nozzle. In addition, a height of the crucible barrel 3 is less than or equal to a height of the discharge pipe 2 to ensure that the material ejected from the discharge pipe 2 is not blocked by the crucible barrel 3, which further improves the uniformity of film formation.

Technical effect of the present disclosure is to provide an evaporation coating apparatus, wherein a substrate is placed on a flat stage, discharge pipes are arranged on the crucible body, a nozzle faces the ground, an evaporation source is located above the substrate, a mask plate is placed between the substrate and the evaporation source, and an evaporation surface of the substrate faces upward. The substrate is evaporation coated under the condition of zero sagging, and the mask will not be squeezed by the substrate, so as to improve the stability and service life of the mask. A fixing device may be simple hardware, which does not need to bear a weight of the substrate itself, and thus is not easy to loosen and displace, and does not require frequent correction. Therefore, the evaporation coating apparatus can effectively improve yield, increase production capacity, save manpower, improve the stability and service life of the fine mask, thus providing a qualitative improvement to the OLED industry.

The evaporation coating apparatus provided by the embodiments of the present application are described in detail above. Specific examples are used to explain the principle and implementation of the present application. The descriptions of the above embodiments are only used to help understand the present application. Also, for those skilled in the art, according to the ideas of the present application, there will be changes in the specific implementation and application scope. In summary, the content of this specification should not be construed as limiting the present application.

What is claimed is:

1. An evaporation coating apparatus, comprising:
a crucible body, wherein the crucible body is a hollow plate comprising a cavity;
a plurality of discharge pipes evenly distributed on a bottom surface of the crucible body, wherein an outlet at one end of each of the plurality of discharge pipes is communicated with the cavity, and the outlet at another end of each of the plurality of discharge pipes faces a ground;
a plurality of crucible barrels, wherein each of the plurality of crucible barrels is disposed between two or more of adjacent ones of the discharge pipes, and each of the plurality of crucible barrels comprises a barrel opening connected to the cavity of the hollow plate; and
a plurality of inlets arranged on a top surface of the crucible body and communicated with the cavity, wherein each of the plurality of inlets is arranged opposite to the barrel opening of each of the plurality of crucible barrels.

2. The evaporation coating apparatus according to claim 1, wherein the crucible body is a flat plate; and a ratio of a volume of the cavity to a volume of the crucible body is 0.7-0.95.

3. The evaporation coating apparatus according to claim 1, wherein the discharge pipes are linear, and a central axis of each of the plurality of discharge pipes is perpendicular to a plane where a bottom surface of the hollow plate is located.

4. The evaporation coating apparatus according to claim 1, wherein a distance between adjacent ones of the discharge pipes is 10-40 mm.

5. The evaporation coating apparatus according to claim 1, further comprising a nozzle connected to the outlet at the another end of each of the plurality of discharge pipes that faces the ground.

6. The evaporation coating apparatus according to claim 5, wherein a ratio of an aperture of the nozzle to an inner diameter of the outlet of each of the plurality of discharge pipes is less than 0.5; or the ratio of the aperture of the nozzle to the inner diameter of the outlet of each of the plurality of discharge pipes is 1.

7. The evaporation coating apparatus according to claim 1, wherein each of the plurality of the crucible barrels is a column having a height less than or equal to a length of each of the plurality of discharge pipes.

8. The evaporation coating apparatus according to claim 1, further comprising an evaporation source, wherein the evaporation source is an electric heating wire surrounding the plurality of crucible barrels and/or the plurality of discharge pipes.

9. The evaporation coating apparatus according to claim 1, wherein the plurality of discharge pipes and the plurality of crucible barrels are arranged in a crucible matrix; and the evaporation source is an electric heating wire surrounding the crucible matrix.

10. The evaporation coating apparatus according to claim 1, further comprising a stage configured to place a substrate; a fixing device installed at an edge of the stage to fix the substrate; and a mask plate disposed above the substrate.
